(19) United States
(12) Patent Application Publication
(10) Pub. No.: US 2025/0221290 A1
(43) Pub. Date: Jul. 3, 2025

(54) FLEXIBLE DISPLAY DEVICE

(71) Applicant: LG Display Co., Ltd., Seoul (KR)

(72) Inventors: Sungjin PARK, Seoul (KR); GyuHo LEE, Seoul (KR)

(21) Appl. No.: 19/001,999

(22) Filed: Dec. 26, 2024

(30) Foreign Application Priority Data
Dec. 29, 2023 (KR) 10-2023-0196623

(51) Int. Cl. H10K 77/10; H10K 102/00

(52) U.S. Cl. CPC H10K 77/111; H10K 2102/311

(57) ABSTRACT

A flexible display device includes a display panel configured to display images and a support substrate disposed under the display panel so as to support the display panel. The support substrate includes a plurality of rigid portions extending in a first direction and spaced apart from each other in a second direction perpendicular to the first direction and an elastic portion disposed to fill between the plurality of rigid portions. On a plane defined in the first direction and the second direction, both side surfaces of each of the plurality of rigid portions include a curved portion having a plurality of protrusions repeated in the first direction and at least one recess.

### CROSS-REFERENCE TO RELATED APPLICATIONS

This application claims priority to Korean Patent Application No. 10-2023-0196623 filed on Dec. 29, 2023, in the Korean Intellectual Property Office, the entire disclosure of which is incorporated herein by reference.

### BACKGROUND

### Technical Field

The present disclosure relates to a display device, and more particularly, but not exclusively, to a flexible display device including a plurality of rigid portions and an elastic portion.

### Description of the Related Art

Recently, as the society advances to the information society, the field of display devices which visually express electrical information signals is rapidly advancing. Thus, various display devices with excellent performance, such as thin profile, lightness, and low power consumption, have been developed. Examples of the display devices include a liquid crystal display (LCD) device, a plasma display panel (PDP) device, a field emission display (FED) device, an organic light emitting display (OLED) device, etc.

Recently, flexible display devices manufactured to display images even when bent, rolled, or folded have received attention as the next-generation display devices. Such display panels present unique challenges relative to conventional displays that are not flexible. For example, bending the display can damage the electrical components of the display and negatively impact their durability. In addition, the layers of the display laminate are more likely to separate or crack as a result of the stress and strain associated with bending or folding the display. Such problems are more likely to occur for display applications that involve multiple repeated folding cycles. Accordingly, it would be advantageous to have a flexible display that overcomes these and other deficiencies with current solutions.

### BRIEF SUMMARY

Flexible display devices can be classified into an unbreakable display device which has a high durability, and a bendable display device which can be bent without breaking. Also, the flexible display devices can be classified into a rollable display device which can be rolled, and a foldable display device which can be folded. Further, the flexible display devices can be classified into a stretchable display device which can be stretched and contracted in a specific direction and changed into various shapes. The flexible display devices are good in space usability, interior, and design and can be applied to various application fields. A flexible substrate is used as a display panel of the flexible display device. To suppress sagging of the display panel and protect the display panel from foreign matters and impacts from the outside, a support substrate, such as a back plate, may be disposed under the display panel.

In one or more embodiments of the present disclosure, a flexible display device is provided in which a load concentrated on a display panel can be efficiently dispersed to improve durability.

In one or more embodiments of the present disclosure, a stretchable display device is provided which can be bent or stretched without damage to a display panel.

In one or more embodiments of the present disclosure, a foldable display device is provided which can be folded in one axis direction without damage to a display panel.

A flexible display device according to an embodiment of the present disclosure includes: a display panel configured to display images; and a support substrate disposed under the display panel so as to support the display panel and including a plurality of rigid portions extending in a first direction and spaced apart from each other in a second direction perpendicular to the first direction and an elastic portion disposed to fill between the plurality of rigid portions. On a plane defined in the first direction and the second direction, both side surfaces of each of the plurality of rigid portions include a curved portion having a plurality of protrusions repeated in the first direction and at least one recess.

According to the present disclosure, rigidity of a display panel can be reinforced and a load concentrated on the display panel can be efficiently dispersed.

According to the present disclosure, flexible driving is possible and a sufficient rigidity for supporting the display panel can be enabled and achieved.

According to the present disclosure, when a display device is tensioned, cracks hardly occur. Thus, the display device can be bent or stretched without damage.

Embodiments of the present disclosure are not limited to the above-mentioned embodiments, and other embodiments, which are not mentioned above, can be clearly understood by those skilled in the art from the following descriptions with reference to the accompanying drawings.

The benefits and advantages according to the present disclosure are not limited to the contents exemplified above, and more various effects, benefits, and advantages are achieved by the embodiments in the present specification.

### BRIEF DESCRIPTION OF THE SEVERAL VIEWS OF THE DRAWINGS

The patent or application file contains at least one drawing executed in color. Copies of this patent or patent application publication with color drawing(s) will be provided by the Office upon request and payment of the necessary fee.

The above and other aspects, features and other advantages of the present disclosure will be more clearly understood from the following detailed description taken in conjunction with the accompanying drawings, in which:

FIG. 1 is a perspective view schematically illustrating a flexible display device according to an embodiment of the present disclosure;

FIG. 2 is an enlarged plan view of area I of the flexible display device shown in FIG. 1 according to an embodiment of the present disclosure;

FIG. 3 is a cross-sectional view taken along a line A-A′ of FIG. 2;

FIG. 4A is a plan view of a support substrate of the flexible display device according to an embodiment of the present disclosure;

FIG. 4B is a cross-sectional view taken along a line B-B′ of FIG. 4A;

FIG. 4C is a cross-sectional view taken along a line C-C′ of FIG. 4A;

FIG. 5 is a plan view of a support substrate of a flexible display device according to an embodiment of the present disclosure;

FIG. 6 is a plan view of a support substrate of a flexible display device according to an embodiment of the present disclosure;

FIG. 7 is a plan view of a support substrate of a flexible display device according to an embodiment of the present disclosure;

FIG. 8 is a plan view of a support substrate of a flexible display device according to an embodiment of the present disclosure;

FIG. 9 is a schematic plan view of a flexible display device according to an embodiment of the present disclosure;

FIG. 10 is a cross-sectional view taken along a line D-D′ of FIG. 9;

FIG. 11 is a plan view of a support substrate in area II of FIG. 9 according an embodiment of the present disclosure;

FIG. 12 is a plan view of a support substrate in area II of FIG. 9 according an embodiment of the present disclosure;

FIG. 13 shows the result of a 5% elongation test simulation of the support substrate shown in FIG. 4A;

FIG. 14 shows the result of a 5% elongation test simulation of the support substrate shown in FIG. 7;

FIG. 15A is a plan view of a support substrate according to a Comparative Example;

FIG. 15B shows the result of a 25% elongation test simulation of the support substrate of the Comparative Example;

FIG. 15C shows the result of a 25% elongation test simulation of the support substrate shown in FIG. 4A;

FIG. 15D shows the result of a 25% elongation test simulation of the support substrate shown in FIG. 8;

FIG. 16A shows the result of a 5% elongation test simulation of the support substrate shown in FIG. 11; and

FIG. 16B shows the result of a 5% elongation test simulation of the support substrate shown in FIG. 12.

### DETAILED DESCRIPTION

Advantages and characteristics of the present disclosure and a method of achieving the advantages and characteristics will be clear by referring to the embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, the element or layer may be directly on the another element or layer, or other element or layer may be interposed therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a flexible display device according to one or more embodiments of the present disclosure will be described in detail with reference to accompanying drawings.

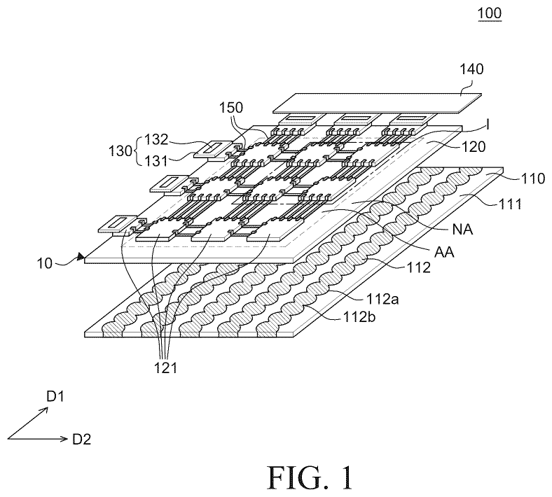

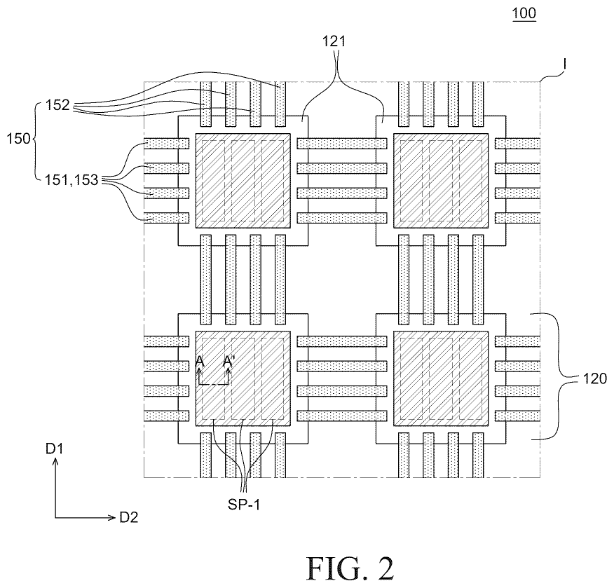

FIG. 1 is a schematic perspective view of a flexible display device 100 according to an embodiment of the present disclosure. FIG. 2 is an enlarged plan view of area I of the flexible display device of FIG. 1 according to an embodiment of the present disclosure.

Referring to FIG. 1 and FIG. 2, the flexible display device 100 may be a stretchable display device or a foldable elongated in a second direction D2, meaning a dimension (i.e., length or width) in the second direction D2 is greater than a dimension (i.e., length or width) in the first direction D1. The flexible display device 100 may include a display panel 10 including a base substrate 120, an individual substrate 121, and a connection line 150, a support substrate 110 disposed under the display panel 10, a Chip on Film (COF) 130, and a printed circuit board 140.

The flexible display device 100 of the present disclosure has been described as a stretchable display device or a foldable display device for the convenience of description. However, these are just examples of the flexible display device, but do not limit the type of the flexible device of the present disclosure. The concepts discussed herein can be applied equally to any other type of display device, as well as outside of the display device context.

The display panel 10 includes the base substrate 120, the individual substrate 121, and the connection line 150.

The base substrate 120 serves to support and protect various components of the flexible display device 100. The base substrate 120 is a malleable substrate and may be made of an insulating material which can be bent or stretched. For example, the base substrate 120 may be made of silicone rubber, such as polydimethylsiloxane (PDMS) or an elastomer, such as polyurethane (PU), among others. Thus, the base substrate 120 may have flexibility, but is not limited thereto.

The base substrate 120 as a malleable substrate can reversibly expand and contract. The base substrate 120 may have an elastic modulus of several to hundreds of MPa and a tensile fracture rate of 100% or more. The base substrate 120 may have a thickness of 10 μm to 1 mm but is not limited thereto.

The base substrate 120 may have a display area AA and a non-display area NA enclosing the display area AA that also corresponding a display area AA and a non-display area NA of the display panel 10.

The display area AA is an area where images are displayed on the flexible display device 100, and display elements and various driving elements for driving the display elements may be disposed in the display area AA. The display area AA includes a plurality of pixels including a plurality of sub-pixels SP_1 best shown in FIG. 2. The plurality of pixels is disposed in the display area AA and includes a plurality of display elements. Each of the plurality of sub-pixels SP_1 may be connected to various lines. For example, each of the plurality of sub-pixels SP_1 may be connected to various lines, such as a gate line, a data line, a high-potential power line, a low-potential power line, and a reference voltage line, even if not specifically shown in the drawings.

The non-display area NA is an area disposed adjacent to the display area AA and enclosing the display area AA. The non-display area NA is an area where no image is displayed, and lines and circuits may be disposed in the non-display area NA. For example, a plurality of pads may be disposed in the non-display area NA, and the pads may be respectively connected to the plurality of sub-pixels SP_1 in the display area AA.

The plurality of individual substrates 121 may be disposed on the base substrate 120. The plurality of individual substrates 121 are rigid substrates that may be spaced apart from each other on the base substrate 120. The plurality of individual substrates 121 may have a relatively higher rigidity than the base substrate 120. That is, the base substrate 120 may be more malleable than the plurality of individual substrates 121, and the plurality of individual substrates 121 may be more rigid than the base substrate 120. The individual substrates 121 provide a relatively rigid base or support for the pixels and sub-pixels SP-1. As a result, the bending or stretching of the display device 100 is primarily enabled by the relatively malleable base substrate 120, and specifically regions of the base substrate 120 between the individual substrates 121. Under similar loads, the individual substrates 121 will not deform or will deform less than the base substrate 120 to protect the sub-pixels SP-1 and avoid damage to the same due to bending or stretching.

The individual substrate 121 may be made of a plastic material having flexibility. For example, the plurality of individual substrates 121 may be made of polyimide (PI), polyacrylate, or polyacetate, among others. However, the material of the individual substrate 121 is not limited thereto.

The plurality of individual substrates 121 may have a higher modulus than the base substrate 120. The modulus is an elastic modulus showing the ratio of stress applied to a substrate to deformation of the substrate caused by stress. When the modulus is relatively high, the rigidity may be relatively high. Accordingly, the plurality of individual substrates 121 may be a plurality of rigid substrates which is more rigid than the base substrate 120. The modulus of the plurality of individual substrates 121 may be 1,000 times higher than that of the base substrate 120 but is not limited thereto.

The connection line 150 may be disposed on the substrate 120 between and connected to the plurality of individual substrates 121.

The connection line 150 may be disposed between the pads disposed on the plurality of individual substrates 121 and may electrically connect the pads. Further details of the connection line 150 will be described below.

The support substrate 110 is disposed under the display panel 10 so as to support the display panel 10. Further details of the support substrate 110 will be described below.

The COF 130 is a film having various components or integrated circuits formed on a malleable base film 131 and may be a flexible printed circuit board in some embodiments. The COF 130 is configured to supply signals to the plurality of sub-pixels SP-1 in the display area AA. The COF 130 may be bonded to the plurality of pads disposed in the non-display area NA of the base substrate 120 and/or display panel 10 and may supply a power voltage, a data voltage, a gate voltage, etc., to the plurality of sub-pixels SP-1 in the display area AA through the pads. The COF 130 includes a base film 131 and a driver IC 132. Also, the COFs 130 may include various other components.

The base film 131 is a layer supporting the driver IC 132 of the COF 130. The base film 131 may be made of an insulating material. For example, the base film 131 may be made of an insulating material having flexibility, including those materials described herein and others.

The driver IC 132 is configured to process data for displaying images and driving signals for processing the data. FIG. 1 illustrates that the driver ICs 132 are mounted in the type of the COF 130, but the present disclosure is not limited thereto. The driver ICs 132 may be mounted by a Chip On Glass (COG) method or a Tape Carrier Package (TCP) method, among others.

A controller, such as an IC chip and a circuit, may be mounted on the printed circuit board 140. A memory, a processor, etc., may also be mounted on the printed circuit board 140, although not shown. The printed circuit board 140 transmits signals for driving the display elements from the controller to the display elements.

The printed circuit board 140 is connected to the COFs 130 and thus can be electrically connected to the plurality of sub-pixels SP-1 on the plurality of individual substrates 121.

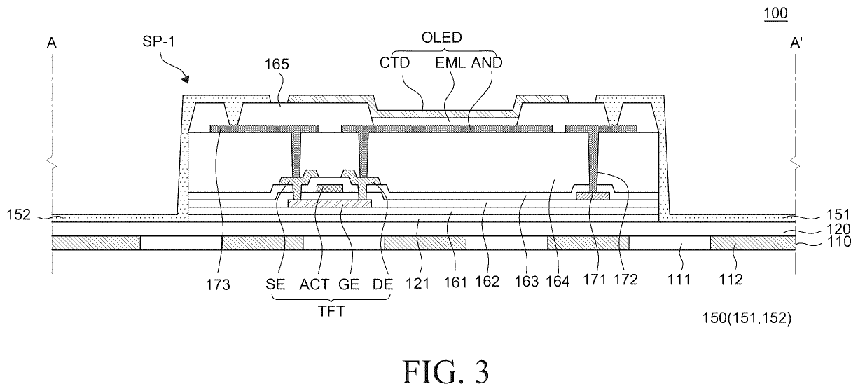

Hereinafter, the flexible display device 100 according to one or more embodiments of the present disclosure will be described in more detail with reference to FIG. 3 with continuing reference to FIG. 1 and FIG. 2.

FIG. 3 is a cross-sectional view taken along a line A-A′ in FIG. 2 providing more detail of a structure of one of the sub-pixels SP-1 in the stretchable display device 100 shown in FIG. 2.

Specifically, FIG. 3 illustrates a part of a cross-sectional structure of one of a red sub-pixel, a green sub-pixel, and a blue sub-pixel for the convenience of description. The structure of the other sub-pixels SP-1 may be similar, unless otherwise stated.

With reference to FIG. 3, and continuing reference to FIG. 1 and FIG. 2, the buffer layer 161 is provided on the plurality of individual substrates 121. That is, the buffer layer 161 may be provided only in an area overlapping the plurality of individual substrates 121. The buffer layer 161 may be made of an inorganic insulating material, such as silicon nitride (SiNx), a silicon oxide (SiOx), and silicon oxynitride (SiON), among others. Therefore, the buffer layer 161 may be more prone to damage, such as cracking, when the flexible display device 100 is elongated. Thus, the buffer layer 161 is patterned in the shape of the plurality of individual substrates 121 without being provided between the plurality of individual substrates 121. Therefore, the buffer layer 161 may be provided only on the plurality of individual substrates 121. In some embodiments, the buffer layer 161 is provided between the substrates 121 as a result of changes in composition or properties of the buffer layer 161. The same is true for any other layer described below as being only on the individual substrates 121.

A thin film transistor TFT including a gate electrode GE, an active layer ACT, a source electrode SE, and a drain electrode DE is provided on the buffer layer 161. Herein, a gate insulating layer 162 and an inter-layer insulating layer 163 are patterned and provided only in an area overlapping the plurality of individual substrates 121. The gate insulating layer 162 and the inter-layer insulating layer 163 may also be made of an inorganic insulating material, similar to the buffer layer 161. Therefore, the gate insulating layer 162 and the inter-layer insulating layer 163 may also be prone to damage, such as cracking, when the flexible display device 100 is elongated. Thus, the gate insulating layer 162 and the inter-layer insulating layer 163 are patterned in the shape of the plurality of individual substrates 121 without being provided between the plurality of individual substrates 121. Therefore, the gate insulating layer 162 and the inter-layer insulating layer 163 may be provided only on the plurality of individual substrates 121.

A gate pad 171 is disposed on the gate insulating layer 162. The gate pad 171 serves to transmit a gate signal to a plurality of sub-pixels. The gate pad 171 may be made of the same material as the gate electrode GE but is not limited thereto.

An overcoating layer 164 may be disposed on the thin film transistor TFT and provided only on the plurality of individual substrates 121. The overcoating layer 164 may include a contact hole for electrically connecting the thin film transistor TFT to the anode AND, a contact hole for electrically connecting a data pad 173 to the source electrode SE, and a contact hole for electrically connecting a connection pad 172 to a gate pad 171.

The data pad 173, the connection pad 172, and an organic light emitting diode OLED may be disposed on the overcoating layer 164.

The data pad 173 may transmit a data signal from a connection line 152, which functions as a data line, to a plurality of sub-pixels. The data pad 173 is connected to the source electrode SE of the thin film transistor TFT through a contact hole formed in the overcoating layer 164.

The connection pad 172 may transmit a gate signal from a connection line 151, which functions as a gate line, to the plurality of sub-pixels SP_1. The connection pad 172 is connected to the gate pad 171 through a contact hole formed in the overcoating layer 164 and the inter-layer insulating layer 163 and transmits a gate signal to the gate pad 171.

The organic light emitting diode OLED is disposed corresponding to each of the plurality of sub-pixels.

FIG. 3 does not illustrate all the components of the sub-pixel SP_1 for the convenience of description. The organic light emitting diode OLED may include the anode AND, a hole injection layer HIL, a hole transport layer HTL, an emission layer EML, an electron transport layer ETL, an electron injection layer EIL, and a cathode CTD.

The anode AND serves to supply holes to the emission layer EML and is made of a conductive material having a high work function. The anode AND may be a transparent conductive layer made of a transparent conductive oxide (TCO). For example, the anode AND may be made of one or more selected from transparent conductive oxides, such as indium-tin-oxide (ITO), indium-zinc-oxide (IZO), indium-tin-zinc oxide (ITZO), tin oxide (SnO₂), zinc oxide (ZnO), indium-copper-oxide (ICO), and aluminum: zinc oxide (Al:ZnO;AZO). However, the present disclosure is not limited thereto.

The hole injection layer HIL for injecting, to the emission layer EML, holes supplied from the anode AND is disposed on the anode AND. The hole injection layer HIL is made of a material for improving the interface characteristics between the anode AND and the hole transport layer HTL and enabling holes to be smoothly injected to the emission layer EML.

For example, the hole injection layer HIL may be made of one or more compounds selected from the group consisting of poly(3,4-ethylenedioxythiophene):poly(styrenesulfonate) (PEDOT:PSS), dipyrazino[2,3-f:2′,3′-h]quinoxaline-2,3,6,7,10.11-hexacarbonitrile (HAT-CN), phthalocyanine (CuPc), N,N′-bis(naphthalene-1-yl)-N,N′-bis(phenyl)-2,2′-dimethylbenzidine (NPD), etc., but is not limited thereto.

The hole transport layer HTL for smoothly transferring holes from the hole injection layer HIL to the emission layer EML may be disposed on the hole injection layer HIL.

For example, the hole transport layer HTL may be selected from the group consisting of N,N′-diphenyl-N,N′-bis(3-methylphenyl)-1,1′-biphenyl-4,4′-diamine (TPD), NPD, MTDATA, 1,3-bis(N-carbazolyl)benzene (mCP), CuPC, TCTA, tris(trifluorovinyl ether)-tris(4-carbazoyl-9-yl-phenyl)amine, (TFV-TCTA), tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, tri-p-tolylamine, N-[1,1′-biphenyl]-4-yl-9,9-dimethyl-N-[4-(9-phenyl-9H-carbazol-3-yl)phenyl]-amine, 4,4′-bis(N-carbazolyl)-1,1′-biphenyl (CBP), and 1,1-bis(4-(N,N′-di(p-tolyl)amino)phenyl)cyclohexane (TAPC), but is not limited thereto.

The hole injection layer HIL or the hole transport layer HTL may be omitted as necessary.

The emission layer EML is disposed on the hole transport layer HTL. The emission layer EML emits light by recombination of electrons and holes. The emission layer EML includes a polymer host and a phosphorescent dopant. The polymer host transfers energy to the phosphorescent dopant so as to improve the luminous efficiency and color purity. Further, the polymer host increases the density of electrons and holes in the emission layer EML to promote recombination of excitons. Therefore, the luminous efficiency can be improved.

A bank 165 includes a contact hole for connecting a connection line 152 functioning as a data line and the data pad 173 and a contact hole for connecting the connection line 151 functioning as a gate line and the connection pad 172.

The cathodes CTD may be patterned to respectively overlap the plurality of individual substrates 121. That is, the cathodes CTD may be provided not between the plurality of individual substrates 121, but only in an area overlapping the plurality of individual substrates 121.

The cathodes CTD are made of a metal material. Thus, if the cathodes CTD are provided even between the plurality of individual substrates 121, the cathodes CTD may be damaged when the flexible display device 100 is stretched and contracted. Accordingly, the cathodes CTD may be disposed corresponding to the respective individual substrates 121 on the plane. Also, the cathodes CTD disposed in the area overlapping the plurality of individual substrates 121 may have an area not overlapping an area where the connection line 150 is disposed. Further, the cathodes CTD are patterned to correspond to the plurality of individual substrate 121. Therefore, each of the cathodes CTD disposed on the plurality of individual substrates 121 can be independently supplied with low-potential power through the connection line 150.

In the flexible display device 100, various lines, such as gate lines, data lines, high-potential power lines, and reference voltage lines, which are made of metal materials, are disposed only on the plurality of individual substrates 121. That is, in the flexible display device 100 according to an embodiment of the present disclosure, various lines made of metal materials may be disposed only on the plurality of individual substrates 121, but not in contact with the base substrate 120. Accordingly, various lines may be patterned to correspond to the plurality of individual substrates 121 and discontinuously disposed.

The connection line 150 is disposed between two adjacent individual substrates 121 to connect the discontinuous lines. The pads on the two adjacent individual substrates 121 may be connected by the connection line 150. That is, the connection line 150 electrically connects the pads on the two adjacent individual substrates 121.

The connection lines 150 include the first connection line 151 and the second connection line 152.

The first connection line 151 may function as a gate line and may electrically connect the gate pads 171 on two individual substrates 121 adjacent to each other in the second direction through the contact hole formed in the bank 165. Accordingly, the gate pads 171 on the plurality of individual substrates 121 may be connected by the first connection line 151 that functions as a gate line, and one gate signal may be transmitted.

The second connection line 152 may function as a data line and may electrically connect the data pads 173 on two individual substrates 121 adjacent to each other in a first direction through the contact hole formed in the bank 165. Accordingly, the data pads 173 on the plurality of individual substrates 121 may be connected by a plurality of second connection lines 152 that functions as data lines, and one data signal may be transmitted.

The LED of the stretchable display device according to an exemplary embodiment of the present disclosure has been illustrated and described as an OLED, for the convenience of description. However, the present disclosure is not limited thereto. That is, a micro-LED may be used as the LED of the stretchable display device according to an embodiment of the present disclosure, among others.

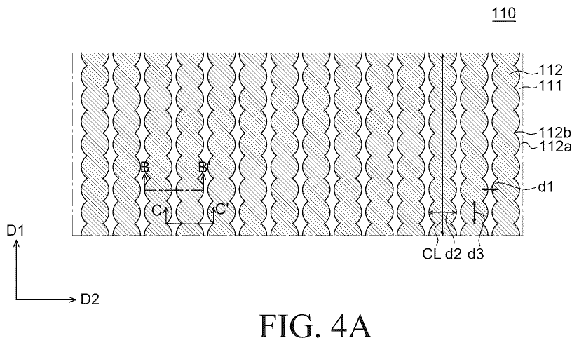

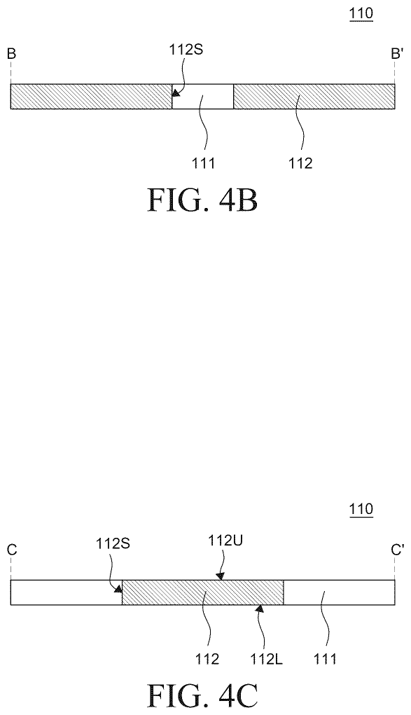

FIG. 4A is a plan view of the support substrate 110 of the flexible display device 100 according to an embodiment of the present disclosure, FIG. 4B is a cross-sectional view of the support substrate 110 taken along a line B-B′ of FIG. 4A, and FIG. 4C is a cross-sectional view of the support substrate 110 taken along a line C-C′ of FIG. 4A.

The support substrate 110 will be described as a component of the flexible display device 100 for the convenience of description. However, the support substrate 110 is not limited to a component of the flexible display device 100. That is, the following detailed descriptions of the support substrate 110 can be equally applied to any flexible display device described herein or others according to various embodiments of the present disclosure without particular limitation. The support substrate 110 may also be applied to other types of displays.

The support substrate 110 may be a composite material which includes a plurality of rigid portions 112 made of a rigid material and an elastic portion 111 made of an elastic material. Therefore, the support substrate 110 may be bent together with the display panel 10 during flexible driving of the flexible display device 100 to support the display panel 10 and reinforce rigidity of the display panel 10. Unless otherwise defined, the word “rigid” means a material with less than 10% stretchability in any one axis before plastic deformation. The word “flexible” means a material with more than 10% stretchability in any one axis before plastic deformation.

The elastic portion 111 may correspond to a base material (matrix) among the materials of the support substrate 110 made of a composite material. In an embodiment, the elastic portion 111 is one or a combination of any of the materials described herein. The elastic portion 111 may be disposed to fill between the plurality of rigid portions 112, and the elastic portion 111 may be disposed to enclose the plurality of rigid portions 112. That is, the plurality of rigid portions 112 may be inserted into the elastic portion 111. Specifically, the elastic portion 111 may be disposed to enclose side surfaces 112S of the plurality of rigid portions 112. The elastic portion 111 may be disposed to expose a part of an upper surface 112U and a lower surface 112L of the rigid portion 112. For example, in an embodiment, the elastic portion 111 and rigid portion 112 may have a similar thickness such that the portions 111, 112 are planar or in plane with each other. As a result, the elastic portion 111 is disposed on and covers side surfaces 112S of the rigid portion 112 while the upper and lower surfaces 112U, 112L of the rigid portion 112 are exposed. In such an embodiment, the upper and lower surfaces 112U, 112L may be outermost top and bottom surfaces or end faces of the rigid portion. Alternatively, the elastic portion 111 may be disposed to cover a part of the upper surface 112U and the lower surface 112L of the rigid portion 112 or disposed to cover all the surfaces 112S, 112U, 112L of the rigid portion 112. Therefore, the rigid portion 112 may be inserted into the elastic portion 111 so as to be enclosed by the elastic portion 111. Accordingly, the elastic portion 111 may serve to fix the positions of the plurality of rigid portions 112.

The elastic portion 111 may have flexibility. Accordingly, when the flexible display device 100 is elongated, the elastic portion 111 may support the display panel 10 while the support substrate 110 is elongated together with the display panel 10.

The elastic portion 111 may be made of an elastic material. For example, the elastic portion 111 may be made of an elastomer material, such as silicone or rubber. Therefore, an elastic modulus of the elastomer material may be 10 MPa to 1400 MPa. However, the material of the elastic portion 111 may vary depending on characteristics demanded for the product and is not limited thereto.

The plurality of rigid portions 112 may be made of a rigid material. The plurality of rigid portions 112 may correspond to a core-shaped reinforcement material among the materials of the support substrate 110 made of a composite material. The rigid portion 112 may have a comparatively high elastic modulus and a low coefficient of thermal expansion CTE relative to the elastic portion 111. Therefore, the rigid portion 112 may increase the elastic restoring force of the support substrate 110 to improve durability of the support substrate 110. Further, the rigid portion 112 may improve a resistance of the support substrate 110 against physical distortion and thermal distortion.

The rigid portion 112 may be made of a high elastic and rigid material, which is any one of polymers, such as vero-black, composite materials, metals, alloys, oxide ceramics, nitride ceramics, and carbide ceramics. Therefore, an elastic modulus of the high elastic and rigid material may be 1 GPa to 1000 GPa. However, the material of the rigid portion 112 may vary depending on characteristics demanded for the product and is not limited thereto.

Referring to FIG. 4A through FIG. 4C, the support substrate 110 is disposed under the display panel 10 so as to support the display panel 10. Also, the support substrate 110 includes the plurality of rigid portions 112 extending in the first direction D1 and spaced apart from each other in the second direction D2 perpendicular to the first direction D1, and the elastic portion 111 disposed to fill between the plurality of rigid portions 112. Further, on a plane defined in the first direction D1 and the second direction D2, such as that shown in FIG. 4A, both side surfaces 112S of each of the plurality of rigid portions 112 include a curved portion having a plurality of protrusions 112a repeated in the first direction D1 and at least one recess 112b. Thus, it is possible to reinforce rigidity of the display panel 10 and also possible to effectively disperse a load concentrated on the display panel 10. Therefore, flexible driving is possible and a sufficient rigidity for supporting the display panel 10 can be secured. Also, when the display device 100 is tensioned, cracks hardly occur, meaning that inclusion of the support substrate 110 significantly reduces or even eliminates the likelihood of cracking depending on tensile load relative to a display without the support substrate 110. Thus, the display device 100 can be bent or stretched without damage. Accordingly, it is preferable that the flexible display device 100 include the support substrate 110.

The both side surfaces 112S of each of the plurality of rigid portions 112 may be symmetrical to each other, meaning that the protrusions 112a and at least one recess 112b generally align with or correspond with each other on both sides 112S of the rigid portions 112.

Each of the plurality of protrusions 112a may have a curved shape having a curvature. For example, each of the plurality of protrusions 112a may have a circular or oval shape or at least partially circular or ovular shape. Each rigid portion 112 may be disposed in a continuous row of alternating protrusions 112a and recesses 112b extending in the first direction D1. As such, the rigid portions 112 formed into, for example, one or more circles or ovals connected to each other in the first direction D1. Also, the one or more circles or ovals may partially overlap each other and thus may extend in the first direction D1. However, the present disclosure is not limited thereto. Since the both side surfaces 112S of each protrusion 112a have a curved shape, the likelihood of cracks occurring even when the display device is elongated in the second direction D2 and durability can be reduced.

A protrusion 112a included in a side surface 112S of one of the plurality of rigid portions 112 may be disposed to be adjacent to a protrusion 112a of another rigid portion 112 adjacent to the one rigid portion 112 in the second direction D2. Specifically, the rigid portions 112 extending in the first direction D1 may have the same shape, and the rigid portions 112 having the same shape may be repeated at a regular interval in the second direction D2. In other words, in some embodiments, the protrusions 112a of each rigid portion 112 are aligned with or correspond to the protrusions 112a of successive ones of the rigid portions 112 in the second direction D2. Thus, stretchability of the flexible display device 100 can be improved and rigidity for supporting the display panel 10 can be further reinforced without overly limiting or otherwise impacting the flexibility of the display device 100 as a result of the elastic portions.

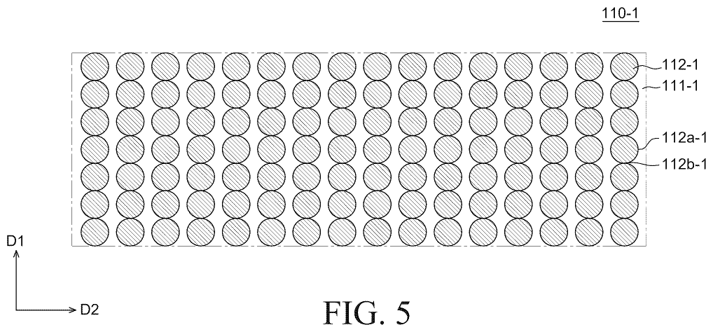

FIG. 5 is a plan view of a support substrate 110-1 of a flexible display device according to an embodiment of the present disclosure. The support substrate 110-1 shown in FIG. 5 is substantially the same as the support substrate 110 shown in FIG. 4A except the shape of a rigid portion 112-1. Therefore, redundant description thereof will be omitted.

Referring to FIG. 5, the support substrate 110-1 of the display device according to an embodiment of the present disclosure may include a plurality of rigid portions 112-1 repeated at a regular interval in the second direction D2. Also, an elastic portion 111-1 may be disposed between the plurality of rigid portions 112-1. Each of the plurality of rigid portions 112-1 may extend in the first direction D1. Also, each of the plurality of rigid portions 112-1 may include a plurality of protrusions 112a-1 and a plurality of recesses 112b-1. The plurality of protrusions 112a-1 and the plurality of recesses 112b-1 may be alternately disposed in each of the plurality of rigid portions 112-1. For example, each of the plurality of rigid portions 112-1 may be formed into a plurality of circles which extends in contact with each other without overlapping in the first direction D1. In other words, in FIG. 4A, the rigid portions 112 include a plurality of successive and interconnected circular areas of rigid material. Those circular areas overlap each other such that each circular area has only a partially circular shape and an interface between successive ones of the circular areas is a section of continuous material with adjoining circular areas of rigid material. In FIG. 5, the circular areas do not overlap, meaning that each circular area is a complete circular and the interface between the circular areas in the rigid portions 112 is at a boundary of successive or adjoining circular areas. As a result, the rigid portions 112 may be coupled to each other at a circumference or outer peripheral edge of a complete circle of rigid material in FIG. 5 and may be, in some aspects, discontinuous.

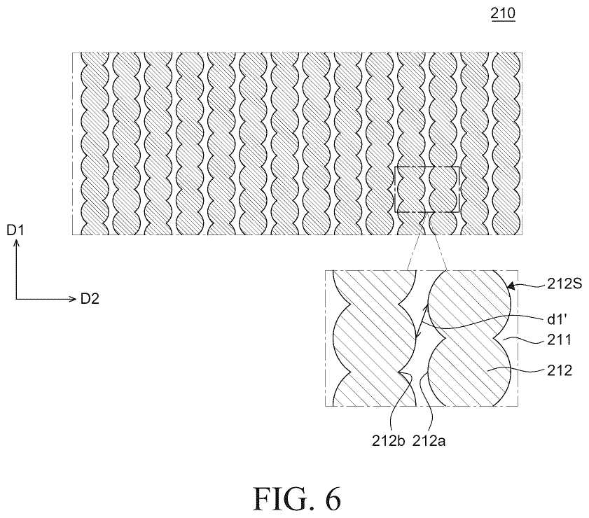

FIG. 6 is a plan view of a support substrate 210 of a flexible display device according to an embodiment of the present disclosure. The support substrate 210 shown in FIG. 6 is substantially the same as the support substrate 110 shown in FIG. 4A except the shape of a rigid portion 212. Therefore, redundant description thereof will be omitted.

Referring to FIG. 6, a protrusion 212a included in a side surface 212S of one of the plurality of rigid portions 212 may be disposed to be adjacent to a recess 212b included in a side surface of another rigid portion 212 adjacent to the one rigid portion 212 in the second direction D2. That is, a protrusion 212a of the rigid portion 212 disposed on or in a first row extending in the first direction D1 may be disposed to be offset from a protrusion 212a of another rigid portion 212 on or in a second row adjacent or successive thereto in the second direction D2. Thus, durability of the flexible display device 100 against elongation can be further improved.

Hereinafter, a distance relationship between components will be described with reference to FIG. 4A and FIG. 6 for the convenience of description. However, the following descriptions are not limited to the embodiments shown in FIG. 4A and FIG. 6 but can be equally applied to all embodiments of the present disclosure.

Referring to FIG. 4A and FIG. 6, the support substrate 110 of FIG. 4A may include a distance d1 between protrusions 112a included in a side surface 112S of one of the plurality of rigid portions 112 and a protrusion 112a of another adjacent or successive rigid portion 112 in the second direction D2. The support substrate 210 of FIG. 6 may include a distance d1′ between protrusions 212a included in a side surface 212S of one of the plurality of rigid portions 212 and a protrusion 212a of another adjacent or successive rigid portion 212 in the second direction D2. The distances d1 and d1′ may be 15 μm to 200 μm. For example, the distance d1 or d1′ may be 15 μm to 150 μm or may be 15 μm to 100 μm. Thus, durability of the flexible display device 100 against elongation can be improved and rigidity can be further reinforced. When the distance d1 or d1′ is less than the above range, durability against elongation may be degraded, and when the distance d1 or d1′ is greater than the above range, rigidity for supporting the display panel of the flexible display device 100 may be degraded. In other words, the distances d1, d1′ in the above ranges correspond to desirable characteristics of the flexible display device 100 such as sufficient support and rigidity for the display panel 10 without overly limiting flexibility. Embodiments may also include support substrates with distances d1, d1′ outside of these ranges, and particularly where material composition or properties of the support substrate and/or rigid portions is adjusted to achieve a desirable balance of rigidity and flexibility.

Referring to FIG. 4A, based on a center line CL of the first direction D1 at the center of each of the plurality of rigid portions 112, a distance d2 between a protrusion 112a included in a side surface 112S of a first one of the plurality of rigid portions 112 and a protrusion 112a included in another side surface 112S facing the side surface 112S with respect to the center line CL may be 2 mm to 4 mm. For example, the distance d2 may be 2 mm to 3 mm. In other words, d2 is a measure of a maximum width of the rigid portions 112 in the second direction D2 and corresponds to an area where the curved side surface 112S of the protrusions 112a extends furthest from both sides of a vertical centerline CL through each rigid portion 112. Thus, durability of the flexible display device 100 against elongation can be improved and rigidity can be further reinforced when the distance d2 is within such a range.

Also, a distance d3 between a recess 112b included in a side surface 112S of one of the plurality of rigid portions 112 and another recess 112b adjacent or successive to the recess 112b in the first direction D1 in the same side surface 112S may be 1.5 mm to 3 mm. For example, the distance d3 may be 1.5 mm to 2 mm. In other words, d3 is a measure of the maximum height of each of curved or circular area in the first direction D1 between successive recesses 112b in the first direction D1. Thus, durability of the flexible display device 100 against elongation can be improved and rigidity can be further reinforced when the distance d3 is within such a range. As above with distances d1 and d1′, the distances d2 and d3 can also be outside of these ranges in further embodiments and with appropriate modifications, if needed, to the structure or composition of the support substrate 110 and/or the rigid portions 112.

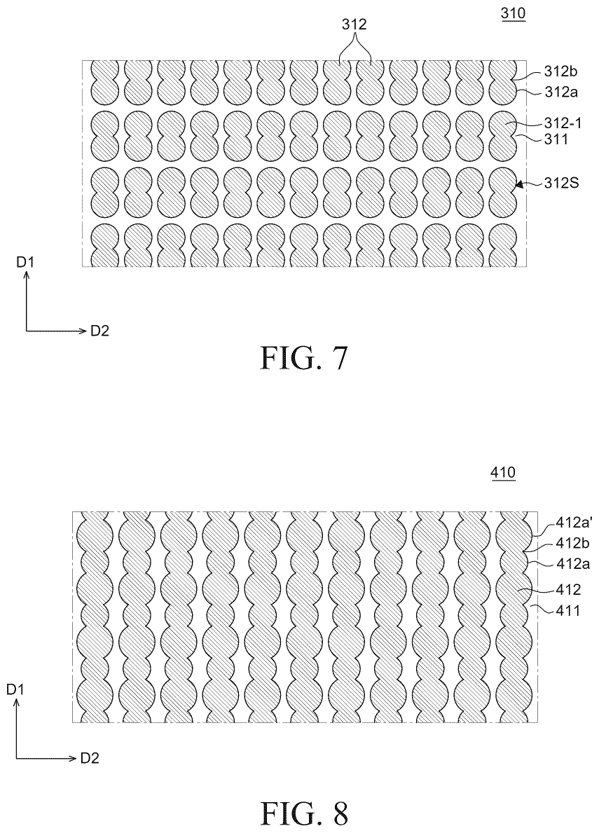

FIG. 7 is a plan view of a support substrate 310 of a flexible display device according to an embodiment of the present disclosure. The support substrate 310 shown in FIG. 7 is substantially the same as the support substrate 110 shown in FIG. 4A except the shape of a rigid portion 312. Therefore, redundant description thereof will be omitted.

Referring to FIG. 7, the support substrate 310 may include a plurality of rigid portions 312 comprised of a plurality of discontinuous and spaced apart sub-rigid portions 312-1 repeated in the first direction D1 and the second direction D2. Herein, both side surfaces 312S of a sub-rigid portion 312-1 may include two protrusions 312a and a recess 312b between the two protrusions 312a. For example, the sub-rigid portion 312-1 may be formed into two circles bonded to each other in the first direction D1 like a snowman but is not limited thereto. In other words, the two circles may partially overlap at an interface thereof such that each circle is a partial circle joined together with the adjacent circular in a continuous structure at the interface between the circles to form a snowman or “8” shape. Since the sub-protrusions 312-1 are spaced apart from each other in the first direction D1 and the second direction D2, when the flexible display device 100 including the sub-protrusions 312-1 is elongated in the first direction D1 as well as in the second direction D2, it is hardly cracked or damaged. That is, durability of the flexible display device 100 against elongation in the first direction D1 can be further improved. In FIG. 7, each of the sub-rigid portions 312-1 is aligned with other sub-rigid portions 312-1 in repeated rows and columns in the first direction D1 and the second direction D2 in a matrix with constant spacing therebetween in both directions D1, D2. In some embodiments, the spacing between sub-rigid portions 312-1 may differ in either or both directions D1, D2 and the sub-rigid portions 312-1 may be offset from other sub-rigid portions 312-1 in successive or in any other row and/or column. In other words, the sub-rigid portions 312-1 may also be arranged in a selected configuration that differs from that shown in FIG. 7.

FIG. 8 is a plan view of a support substrate 410 of a flexible display device according to an embodiment of the present disclosure. The support substrate 410 shown in FIG. 8 is substantially the same as the support substrate 110 shown in FIG. 4A except the shape of a rigid portion 412. Therefore, redundant description thereof will be omitted.

Referring to FIG. 8, a plurality of protrusions 412 may be alternately disposed in each of the rigid portions 412 in the first direction D1 and may include a first protrusion 412a and a second protrusion 412a′ different from each other in at least one characteristic, such as size or curvature, among others. For example, the first protrusion 412a and the second protrusion 412a′ may be alternately disposed in the first direction D1. Since the first protrusion 412a and the second protrusion 412a′ are different from each other in size and/or curvature are alternately disposed in the first direction D1, the flexible display device 100 including the first protrusion 412a and the second protrusion 412a′ may have a higher stretchability. Thus, durability against elongation can be further improved. In an embodiment, the first protrusion 412a is smaller than the second protrusion 412a′ and each rigid portion 412 includes a repeating pattern of alternating first and second protrusions 412a, 412a′ in the first direction D1. Other variations are contemplated, such as at least different patterns. For example, each rigid portion 412 may include a repeated pattern of two or more first protrusions 412a followed by one second protrusion 412a′ or one first protrusion 412a followed by two or more second protrusions 412a′. The pattern of each rigid portion 412 may also include a selected order of first and second protrusions 412a, 412a′ that may be the same or different than the other rigid portions 412. In addition, further protrusions of different sizes and curvatures are contemplated in each rigid portion 412 or only selected ones of the rigid portions 412.

As should be clear from the above, the present disclosure is not particularly limited in the shape or arrangement of the rigid portions. For example, the rigid portions can each have the same configuration or may have different configurations. The protrusions of the rigid portions can be aligned or offset, and spaced from each other and from successive rigid portions by selected distances. In each, different radii of curvature and sizes are contemplated. The protrusions or areas of rigid material can be overlapping or may be connected at outer peripheral edges thereof, or may be discontinuous. While FIGS. 4A-8 illustrate variations on circular or partially circular areas of the rigid portions, any other shape is contemplated herein. In some non-limiting examples, the rigid portions may have a straight line shape with or without protrusions and recesses in either direction D1, D2, may have a curved shape with or without protrusions or recesses in either direction D1, D2, may have a zig zag or step up or step down shape in either direction D1, D2, or the protrusions may be ovular, triangular, trapezoidal, diamond shaped, rectangular shaped, square shaped, have a shape of a parallelogram, a polygonal shape of any selected number of sides, a trefoil shape, a cross shape, a semicircular or partially circular shape, a rhombus shape, a kite shape, an elliptical shape, a crescent shape, or an irregular shape that does not fit into one of the above categories, among others. As will be explained further below, circular or ovular shapes in the rigid portions are generally preferred because they exhibit the best performance during stress testing, although the disclosure is not limited thereto.

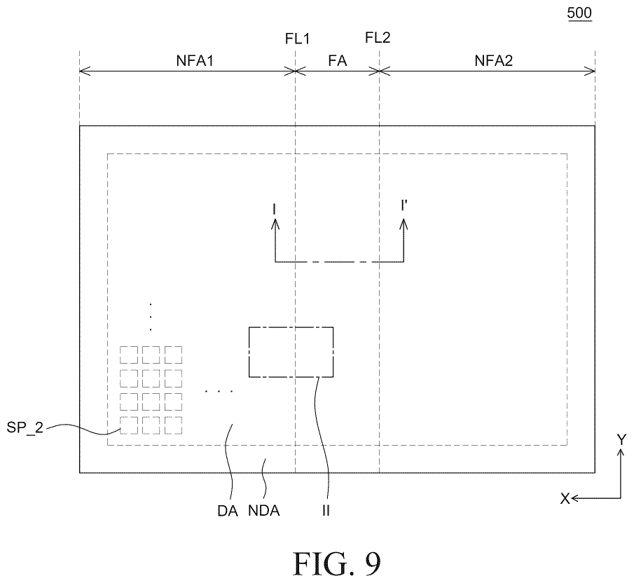

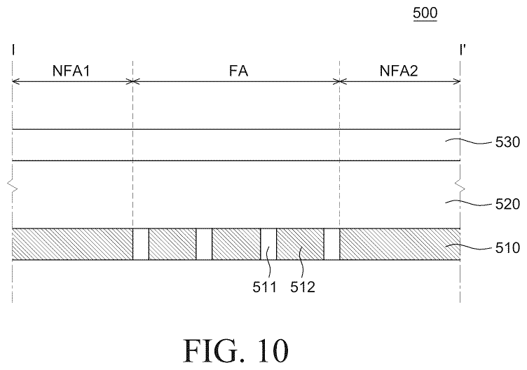

FIG. 9 is a schematic plan view of a flexible display device 500 according to an embodiment of the present disclosure, and FIG. 10 is a cross-sectional view taken along a line D-D′ of FIG. 9.

Referring to FIG. 9 and FIG. 10, the flexible display device 500 may be a foldable display device. The flexible display device 500 may include a support substrate 510, a display panel 520, and a cover window 530.

In describing the flexible display device 500 shown in FIG. 9 and FIG. 10, all the above descriptions regarding the support substrates with reference to FIG. 4A through FIG. 8 as well as the following descriptions can be equally applied to the support substrate 510.

The display panel 520 includes a display area DA and a non-display area NDA. Also, the display panel 520 includes a folding area FA and non-folding areas NFA1 and NFA2. The display panel 520 may be divided into the display area DA and the non-display area NDA depending on whether it can display images or based on areas in which the display panel 520 does and does not display images. Also, the display panel 520 may be divided into the folding area FA and the non-folding areas NFA1 and NFA2 depending on whether or where it is foldable. Therefore, a part of the display panel 520 may serve as a display area DA and a folding area FA, and another part of the display panel 520 may serve as a non-display area NDA and a non-folding area NFA, or any combination thereof.

The display panel 520 includes the folding area FA which is foldable and the non-folding areas NFA1 and NFA2 excluding the folding area FA. The folding area FA is an area which is folded when the flexible display device 500 is folded and is folded in accordance with a specific radius of curvature with respect to folding axes FL1 and FL2. For example, the folding axes FL1 and FL2 of the folding area FA may be defined in the first direction D1 and the non-folding areas NFA1 and NFA2 may extend from the folding area FA in the second direction D2 perpendicular to the folding axes FL1 and FL2. When the folding area FA is folded with respect to the folding axes FL1 and FL2, the folding area FA may form a part of a circle or an oval. Herein, the radius of curvature of the folding area FA may refer to a radius of a circle or an oval formed by the folding area FA.

The non-folding areas NFA1 and NFA2 are areas which are not folded when the flexible display device 500 is folded. That is, the non-folding areas NFA1 and NFA2 maintain a flat state when the flexible display device 500 is folded. The non-folding areas NFA1 and NFA2 may be located on both sides of the folding area FA. That is, the non-folding areas NFA1 and NFA2 may extend in the second direction D2 with respect to the folding axes FL1 and FL2. Herein, the folding area FA may be defined between the non-folding areas NFA1 and NFA2. Further, when the flexible display device 500 is folded with respect to the folding axes FL1 and FL2, the non-folding areas NFA1 and NFA2 may overlap or face each other.

The support substrate 510 is disposed under the display panel 520. Thus, like the display panel 520, the support substrate 510 may include the folding area FA in which the folding axes FL1 and FL2 are defined in the first direction D1 and which is foldable, and the non-folding areas NFA1 and NFA2 excluding the folding area FA. The folding area FA may be composed of a plurality of rigid portions 512 extending in the first direction D1 and spaced apart from each other in the second direction D2 perpendicular to the first direction D1, and an elastic portion 511 disposed to fill between the plurality of rigid portions 512. Also, the non-folding areas NFA1 and NFA2 may be composed of only rigid portions 512. Thus, in the folding area FA where the display panel 520 can be elongated, durability against elongation or bending as well as rigid for supporting the display panel can be secured. Further, in the non-folding areas NFA1 and NFA2 where the display panel 520 is not deformed, excellent rigidity for supporting the display panel 520 can be secured. In other words, in some embodiments where the display devices described herein are not stretchable or bendable across an entirety of the display or active area of the display, but rather, have a specific folding area FA, the rigid portions surrounded by elastic portions described in detail with reference to FIGS. 4A-8 can be included in the folding area FA, while the non-folding area(s) NFA include only rigid material.

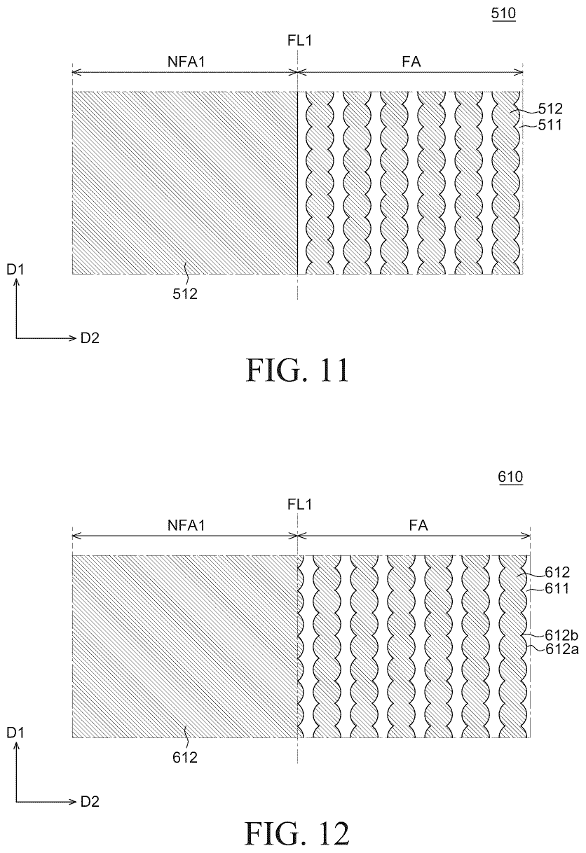

FIG. 11 and FIG. 12 are plan views of embodiments of a support substrate in an area II of FIG. 9. The support substrate 510 shown in FIG. 10 and a support substrate 610 shown in FIG. 11 are substantially the same as the support substrate 110 shown in FIG. 4A except an area where the rigid portion 512 is formed and disposed. Therefore, redundant description thereof will be omitted.

Referring to FIG. 11 and FIG. 12, only a rigid portion 512 or 612 (i.e., the flexible portion is absent) may be disposed in the non-folding area NF1 of the support substrate 510 or 610 of the flexible display device 500. Also, a plurality of rigid portions 512 or 612 extending in the first direction D1 and an elastic portion 511 or 611 disposed to fill the plurality of rigid portions 512 or 612 may be disposed in the folding area FA. Herein, details of the plurality of rigid portions 512 or 612 and the elastic portion 511 or 611 disposed in the folding area FA may be the same as described above.

Referring to FIG. 11, the elastic portion 511 may be disposed in the folding area FA adjoining the folding axis FL1 which is a boundary surface between the folding area FA and the non-folding area NF1. In other words, the elastic portion 511 is present at an interface between the non-folding areas NFA1, NFA2 and the folding area FA.

Referring to FIG. 12, a rigid portion including a curved portion having a plurality of protrusions 612a repeated in the first direction D1 and at least one recess 612b may be disposed on a side surface facing the folding area FA with respect to the folding axis FL1 which is the boundary surface between the folding area FA and the non-folding area NF1. Thus, a contact area at the boundary surface of the folding axis FL1 increases. Therefore, it is possible to suppress the occurrence of cracks or damage caused by tension applied to the boundary surface during folding of the folding area FA. Also, it is possible to improve durability at the boundary surface. In other words, a part of a rigid portion 612 may be disposed on the folding axis FL1 (and folding axis FL2) with protrusions 612a extending and facing inward toward the folding area FA and away from the non-folding areas NFA1, NFA2, unlike FIG. 11 where the flexible portion 511 is present at the folding axis FL1 (and folding axis FL2). Such an arrangement may increase rigidity and support at the folding axis FL1, FL2 to avoid cracks at this location.

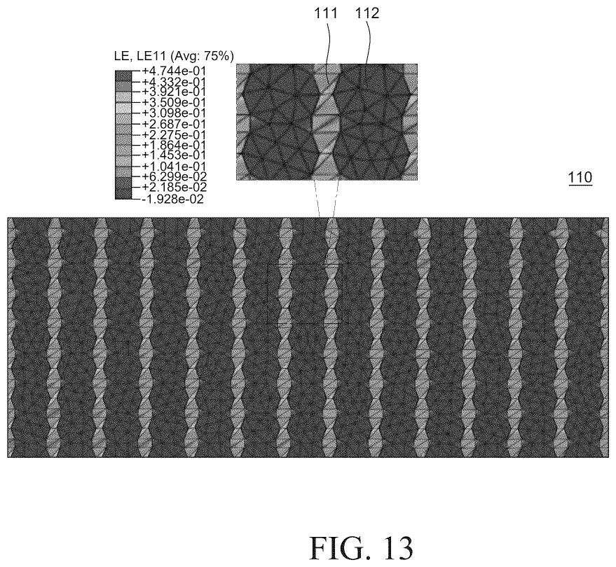

Hereinafter, the results of elongation test simulations of respective support substrates according to Comparative Example and embodiments will be described with reference to FIG. 13 through FIG. 16B. FIGS. 13, 14, and 15B-16B are provided in color to show areas of differing deformation stress. In the color drawings, a gradient or spectrum is provided to demonstrate different levels of stress. The gradient begins at the bottom with blue representing areas of low deformation stress. At the top or upper end of the gradient and/or spectrum is red, which represents areas of high deformation stress. The colors in between blue and red represent intermediate stress with shades of blue, teal, and green representing low to medium stress, respectively, and green, yellow, and orange representing medium to high stress, respectively. The “low” and “high” deformation stress can also be represented by a number, such as those shown in the gradient to identify the different colors and corresponding deformation stress. The units for the gradient measurements may be standard dimensions for measurement of stress, such as newtons per meter squared (N/m2), pounds per square inch (lb/in2) or others.

FIG. 13 shows the result of a 5% elongation test simulation of the support substrate 110 shown in FIG. 4A.

Referring to FIG. 13, it can be seen that even if a plurality of elastic portions 111 disposed between a plurality of rigid portions 112 causes elongation and contraction when the support substrate 110 shown in FIG. 4A is elongated with 5% strain, deformation stress applied to the entire support substrate 110 is low, as most areas are blue or green and only a few areas approach yellow and/or orange in terms of stress level.

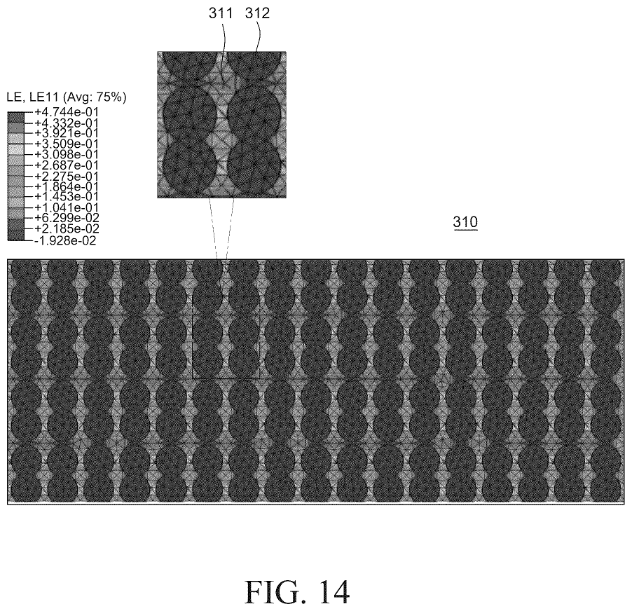

FIG. 14 shows the result of a 5% elongation test simulation of the support substrate 310 shown in FIG. 7.

Referring to FIG. 14, it can be seen that even if a plurality of elastic portions 311 disposed between a plurality of rigid portions 312 causes elongation and contraction when the support substrate 310 shown in FIG. 7 is elongated with 5% strain, deformation stress applied to the entire support substrate 310 is likewise low. While the stress pattern for the substrate 310 differs from FIG. 13, both stress patterns overall exhibit majority low stress characteristics. The elastic portions 311 exhibit higher stress, as intended, because those sections deform during the 5% strain test while the rigid portions 312 do not deform. But even the elastic portions 311 include a color pattern that is largely colors at the lower end of the stress spectrum.

Also, the support substrate 310 shown in FIG. 7 may include at least one gap or space between a plurality of rigid portions 312 in the first direction D1. The at least one gap or space is filled with elastic material 311. Thus, it can be seen that in the at least one gap, deformation stress applied when elongation and contraction occurs is further reduced. Therefore, it can be seen that deformation stress applied to the entire support substrate 310 during elongation and contraction is further reduced.

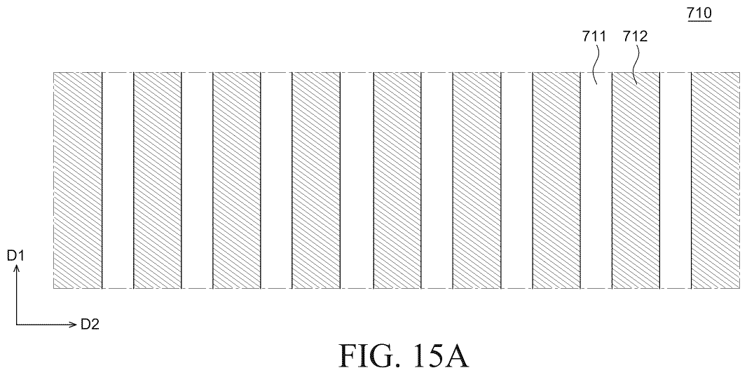

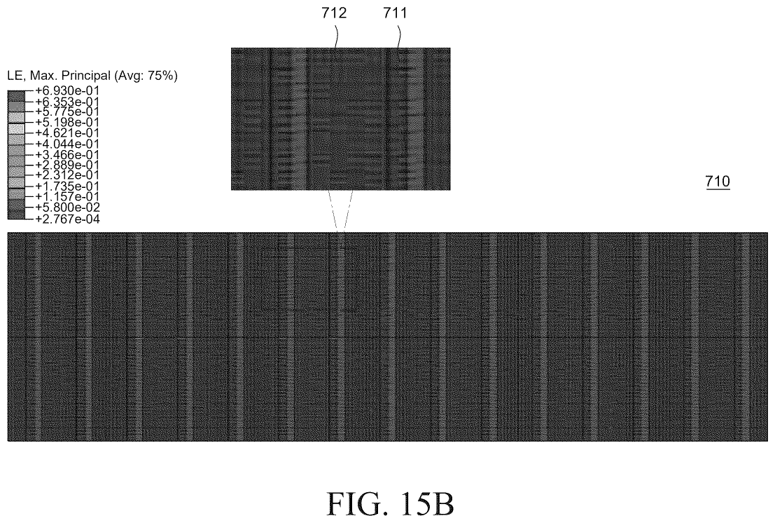

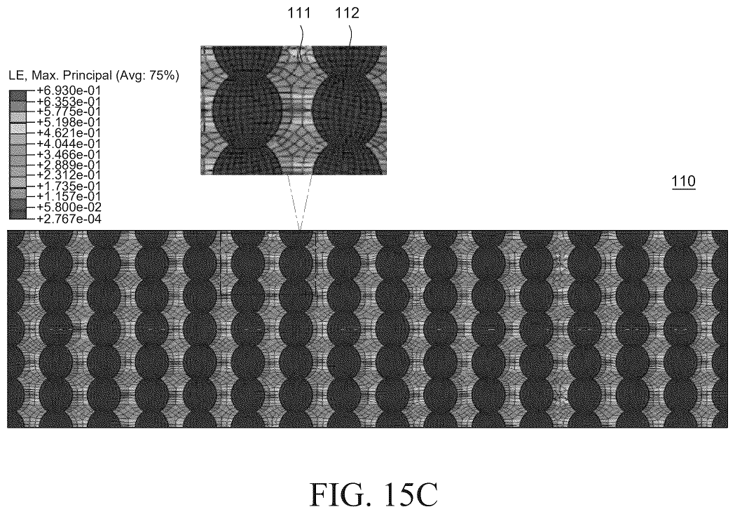

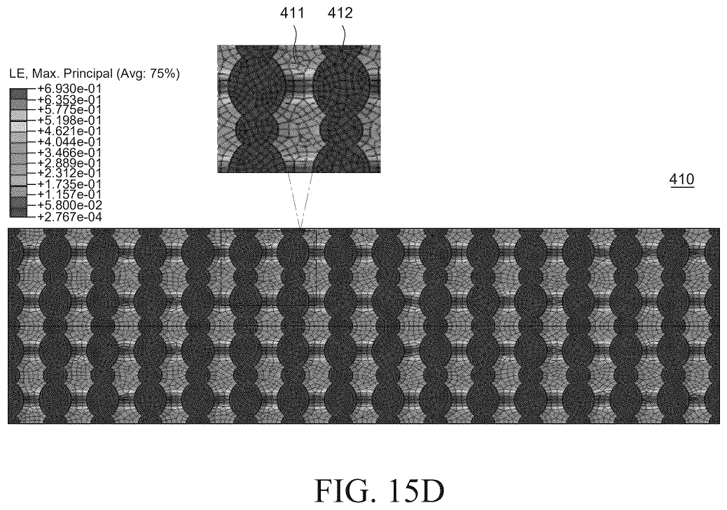

FIG. 15A is a plan view of a support substrate 710 according to a Comparative Example, and FIG. 15B shows the result of a 25% elongation test simulation of the support substrate 710 of Comparative Example.

Referring to FIG. 15A, the support substrate 710 of the Comparative Example includes a plurality of rigid portions 712 disposed at a regular interval in the second direction D2 and a plurality of elastic portions 711 disposed between the plurality of rigid portions 712. Herein, the plurality of rigid portions 712 may extend in a straight line in the first direction D1. That is, both side surfaces of each of the plurality of rigid portions 712 may be straight.

Referring to FIG. 15B, the support substrate 710 of Comparative Example includes the plurality of rigid portions 712 extending in a straight line in the first direction D1. Thus, when the support substrate 710 is elongated with 25% strain, deformation stress applied to the plurality of elastic portions 711 is high, as shown by solid or completely red coloration in FIG. 15B. Also, it can be seen that the average of deformation stress applied to the entire support substrate 710 is as high as 99.6%.

FIG. 15C shows the result of a 25% elongation test simulation of the support substrate shown 110 in FIG. 4A, and FIG. 15D shows the result of a 25% elongation test simulation of the support substrate 410 shown in FIG. 8.

Referring to FIG. 15C, it can be seen that when the support substrate 110 shown in FIG. 4A is elongated with 25% strain, deformation stress applied to the entire support substrate 110 is low compared to the support substrate 710 of Comparative Example, as indicated by the color pattern in the elastic portion 111 of the substrate.

Referring to FIG. 15D, it can be seen that when the support substrate 410 shown in FIG. 8 is elongated with 25% strain, deformation stress applied to the entire support substrate 410 is low compared to the support substrate 710 of Comparative Example. In both FIGS. 15C and 15D, the difference in deformation stress relative to the Comparative Example is immediately apparent, as both the substrates 110, 410 of FIGS. 15C and 15D contain mostly green coloration at the elastic portions with some isolated areas of yellow and/or orange instead of being entirely high stress or red as in FIG. 15B. Overall, these images illustrate that the deformation stress is greatly reduced by the concepts of the disclosure.

Accordingly, it can be seen that if a side surface of each of the plurality of rigid portions has a curved shape with elastic material therebetween, deformation stress applied to the entire support substrate during elongation and contraction is reduced.

Also, the averages of deformation stress applied to the entire support substrates 110 and 410 are calculated based on the results of 25% elongation test simulations of the support substrate 110 shown in FIG. 4A and the support substrate 410 shown in FIG. 8. According to the results of the 25% elongation test simulations, the average of deformation stress applied to the entire support substrate 110 shown in FIG. 4A is 23.2%, and the average of deformation stress applied to the entire support substrate 410 shown in FIG. 8 is 19.8%. Thus, it can be seen that if a side surface of each of the plurality of rigid portions 412 includes the protrusions 412a and 412a′ different from each other in curvature, deformation stress applied to the entire support substrate 410 including the same is further reduced, with embodiments of the disclosure generally greatly reducing the stress of the entire substrate relative to the comparative example.

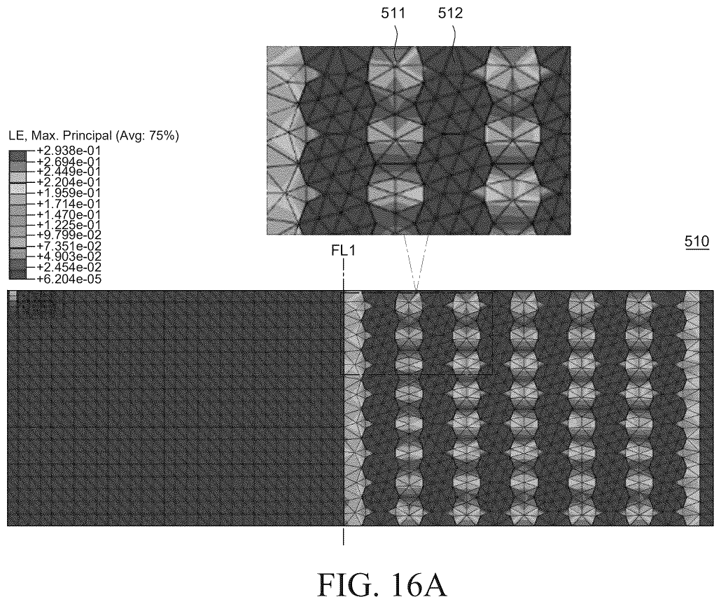

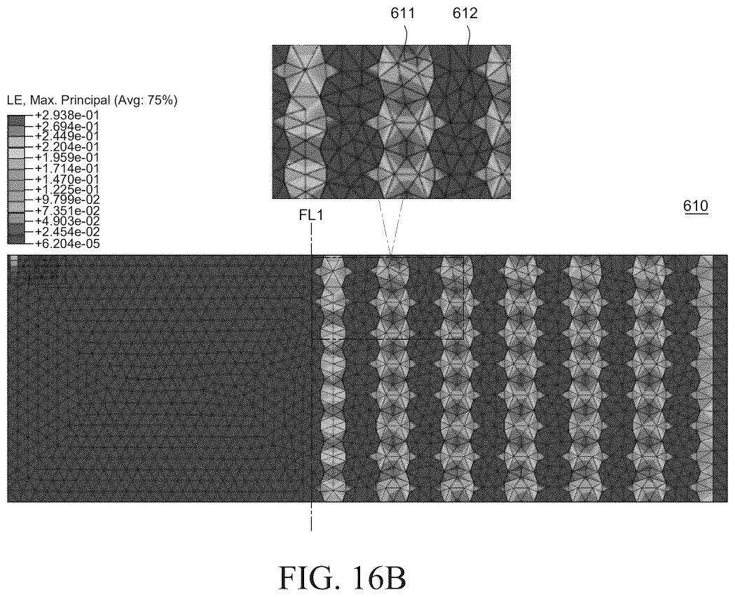

FIG. 16A shows the result of a 5% elongation test simulation of the support substrate shown 510 in FIG. 11, and FIG. 16B shows the result of a 5% elongation test simulation of the support substrate 610 shown in FIG. 12.

Referring to FIG. 16A and FIG. 16B, it can be seen that when each of the support substrate 510 shown in FIG. 11 and the support substrate 610 shown in FIG. 12 is elongated with 5% strain, deformation stress applied to the entire support substrates 510 and 610 is low relative to the Comparative Example, but may be higher in some areas that other examples of the disclosure discussed herein.

Also, the averages of deformation stress applied to the entire support substrates 510 and 610 are calculated based on the results of 5% elongation test simulations of the support substrate 510 shown in FIG. 11 and the support substrate 610 shown in FIG. 12. According to the results of the 5% elongation test simulations, the average of deformation stress applied to the entire support substrate 510 shown in FIG. 11 is 10.9%, and the average of deformation stress applied to the entire support substrate 610 shown in FIG. 12 is 9.1%. Thus, it can be seen that if the rigid portion 612 is disposed in the folding area FA adjoining the folding axis FL1, deformation stress applied to the entire support substrate 610 is further reduced. FIGS. 16A and 16B are primarily provided to demonstrate that adding the rigid portion 612 along the folding axis FL1 further reduces stress relative to embodiments that exclude the rigid portion 612 at the folding axis FL1, or in other words, demonstrate the benefits of the rigid portion 612 being provided along the folding axis FL1.

In view of the above, embodiments of the present disclosure can also be described or summarized as follows.

According to an aspect of the present disclosure, there is provided a flexible display device. The flexible display device comprises a display panel configured to display images; and a support substrate disposed under the display panel so as to support the display panel and including a plurality of rigid portions extending in a first direction and spaced apart from each other in a second direction perpendicular to the first direction and an elastic portion disposed to fill between the plurality of rigid portions, wherein on a plane defined in the first direction and the second direction, both side surfaces of each of the plurality of rigid portions include a curved portion having a plurality of protrusions repeated in the first direction and at least one recess.

Each of the plurality of protrusions may have a curvature of a circular or oval shape.

The plurality of protrusions may be alternately disposed in the first direction and include a first protrusion and a second protrusion different from each other in curvature.

The both side surfaces of each of the plurality of rigid portions may be symmetrical to each other.

Each of the plurality of rigid portions may include a plurality of sub-rigid portions repeated and spaced apart from each other in the first direction.

Both side surfaces of the sub-rigid portion may include two protrusions and a recess between the two protrusions.

A protrusion included in a side surface of one of the plurality of rigid portions may be disposed to be adjacent to a protrusion of another rigid portion adjacent to the one rigid portion in the second direction.

The plurality of rigid portions may have the same shape and be repeated at a regular interval in the second direction.

A protrusion included in a side surface of one of the plurality of rigid portions may be disposed to be adjacent to a recess included in a side surface of another rigid portion adjacent to the one rigid portion in the second direction.

A distance between a protrusion included in a side surface of one of the plurality of rigid portions and a protrusion of another rigid portion adjacent to the one rigid portion in the second direction may be 15 μm to 200 μm.

Based on a center axis of the first direction at the center of each of the plurality of rigid portions, a distance between a protrusion included in a side surface of one of the plurality of rigid portions and a protrusion included in another side surface facing the side surface with respect to the center axis may be 2 mm to 4 mm.

A distance between a recess included in a side surface of one of the plurality of rigid portions and another recess adjacent to the recess in the first direction in the same side surface may be 1.5 mm to 3 mm.

The plurality of rigid portions may be made of a high elastic and rigid material including any one of polymers including vero-black, composite materials, metals, alloys, oxide ceramics, nitride ceramics, and carbide ceramics.

An elastic modulus of the high elastic and rigid material may be 1 GPa to 1000 GPa.

The elastic portion may be made of an elastomer material including silicone or rubber.

An elastic modulus of the elastomer material may be 10 MPa to 1400 MPa.

The flexible display device may be a stretchable display device which is elongated in the second direction. And the display panel includes a base substrate; a plurality of individual substrates on which a plurality of pixels is defined and which is spaced apart from each other; and a connection line which electrically connects pads disposed on individual substrates adjacent to each other among the plurality of individual substrates.

The flexible display device may be a foldable display device. And the support substrate may further include a folding area in which a folding axis is defined in the first direction and which is foldable; and a non-folding area excluding the folding area. The folding area may be composed of a plurality of rigid portions extending in the first direction and spaced apart from each other in the second direction perpendicular to the first direction, and an elastic portion disposed to fill between the plurality of rigid portions, and the non-folding area may be composed of only a rigid portion.

A rigid portion including a curved portion having a plurality of protrusions repeated in the first direction and at least one recess may be disposed on a side surface facing the folding area at a boundary surface between the folding area and the non-folding area.

In an embodiment, a flexible display device includes: a display panel; a support substrate disposed on the display panel, the support substrate extending in a first direction and a second direction perpendicular to the first direction, the support substrate including a plurality of rigid portions extending in the first direction and spaced from each other in the second direction, and an elastic portion disposed between the plurality of rigid portions, wherein at least one of the plurality of rigid portions includes a plurality of protrusions and a recess.

In an embodiment, each of the plurality of rigid portions includes the plurality of protrusions and the recess, and wherein the plurality of protrusions of each of the plurality of rigid portions are aligned with each other in the second direction.

In an embodiment, each of the plurality of rigid portions includes the plurality of protrusions and the recess, and wherein a first one of the plurality of protrusions of a first one of the plurality of rigid portions is aligned with the recess of a second one of the plurality of rigid portions in the second direction.

In an embodiment, the plurality of rigid portions include a plurality of sub-portions that are spaced from each other in the first direction.

In an embodiment, the plurality of rigid portions are continuous in the first direction.

In an embodiment, the plurality of protrusions includes a first protrusion and a second protrusion having a different curvature or size than the first protrusion.

In an embodiment, a flexible display device includes: a display panel; a support substrate disposed on the display panel, the support substrate including a plurality of rigid portions, each of the plurality of rigid portions including a first protrusion, a second protrusion, and a recess between the first protrusion and the second protrusion, and an elastic portion disposed between the plurality of rigid portions.

In an embodiment, a size of the first protrusion is different from a size of the second protrusion.

In an embodiment, the first protrusion and the second protrusion are continuous as a single body.

In an embodiment, the plurality of rigid portions are spaced apart from each other in a first direction and a second direction of the support substrate, and wherein the second direction is perpendicular to the first direction.

In an embodiment, the flexible display device further includes a space between each of the plurality of rigid portions, wherein the elastic portion fills the space between each of the plurality of rigid portions.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The scope of the present disclosure should be construed to include all of the technical concepts described herein and equivalent scope thereof. The scope of the claims is not limited by the disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A flexible display device, comprising:
a display panel configured to display images; and
a support substrate disposed under the display panel and configured to support the display panel, the support substrate including a plurality of rigid portions extending in a first direction and spaced apart from each other in a second direction perpendicular to the first direction, the support substrate further including an elastic portion disposed between the plurality of rigid portions,
wherein each of the plurality of rigid portions includes a first side surface and a second side surface, and
wherein at least one of the first side surface and the second side surface is at least partially curved and includes a first protrusion, a second protrusion, and a recess between the first protrusion and the second protrusion.

2. The flexible display device according to claim 1, wherein the second protrusion has a different curvature than the first protrusion, and
wherein the first protrusion and the second protrusion are two of a plurality of protrusions including the first protrusion and the second protrusion repeated and alternately disposed in the first direction along each of the plurality of rigid portions.

3. The flexible display device according to claim 1, wherein the first side surface and the second side surface of each of the plurality of rigid portions are symmetrical to each other.

4. The flexible display device according to claim 1, wherein each of the plurality of rigid portions includes a plurality of sub-rigid portions repeated and spaced apart from each other in the first direction.

5. The flexible display device according to claim 4, wherein each of the plurality of sub-rigid portions includes the first side surface, the second side surface, and the at least one of the first side surface and the second side surface including the first protrusion and the second protrusion separated by the recess, and
wherein the support substrate includes at least one gap between the plurality of sub-rigid portions in the first direction.

6. The flexible display device according to claim 1, wherein the plurality of rigid portions includes a first rigid portion and a second rigid portion successive to the first rigid portion in the second direction, and
wherein the first protrusion included in the at least one of the first side surface and the second side surface of the first rigid portion is disposed to be adjacent to the first protrusion of in the at least one of the first side surface and the second side surface of the second rigid portion.

7. The flexible display device according to claim 6, wherein each of the plurality of rigid portions has a same shape and is repeated at a regular interval in the second direction.

8. The flexible display device according to claim 1, wherein the plurality of rigid portions includes a first rigid portion and a second rigid portion successive to the first rigid portion in the second direction, and
wherein the first protrusion in the at least one of the first side surface and the second side surface of the first rigid portion is disposed to be adjacent to the recess in the at least one of the first side surface and the second side surface of the second rigid portion.

9. The flexible display device according to claim 1, wherein a distance between the first protrusion of a first one of the plurality of rigid portions and the first protrusion of a second one of the plurality of rigid portions adjacent to the first one of the plurality of rigid portions in the second direction is 15 μm to 200 μm, or
wherein a width of the first protrusion or the second protrusion is 2 mm to 4 mm, or
wherein a height of the first protrusion or the second protrusion is 1.5 mm to 3 mm.

10. The flexible display device according to claim 1, wherein one of the plurality of rigid portions is disposed at a folding axis of the support substrate with the first protrusion and the second protrusion of the one of the plurality of rigid portions facing toward a folding area of the support substrate.

11. A flexible display device, comprising:
a display panel;
a support substrate disposed on the display panel, the support substrate extending in a first direction and a second direction perpendicular to the first direction, the support substrate including:
a plurality of rigid portions extending in the first direction and spaced apart from each other in the second direction; and
an elastic portion disposed between the plurality of rigid portions,
wherein at least one of the plurality of rigid portions includes a plurality of protrusions and a recess.

12. The flexible display device of claim 11, wherein each of the plurality of rigid portions includes the plurality of protrusions and the recess, and
wherein the plurality of protrusions of each of the plurality of rigid portions are aligned with each other in the second direction.

13. The flexible display device of claim 11, wherein each of the plurality of rigid portions includes the plurality of protrusions and the recess, and
wherein a first one of the plurality of protrusions of a first one of the plurality of rigid portions is aligned with the recess of a second one of the plurality of rigid portions in the second direction.

14. The flexible display device of claim 11, wherein the plurality of rigid portions are continuous in the first direction.

15. The flexible display device of claim 11, wherein the plurality of protrusions includes a first protrusion and a second protrusion having a different curvature or size than the first protrusion.

16. A flexible display device, comprising:
a display panel;
a support substrate disposed on the display panel, the support substrate including:
a plurality of rigid portions, each of the plurality of rigid portions including a first protrusion, a second protrusion, and a recess between the first protrusion and the second protrusion; and
an elastic portion disposed between the plurality of rigid portions.

17. The flexible display device of claim 16, wherein a size of the first protrusion is different from a size of the second protrusion.

18. The flexible display device of claim 16, wherein the first protrusion and the second protrusion are continuous as a single body.

19. The flexible display device of claim 16, wherein the plurality of rigid portions are spaced apart from each other in a first direction and a second direction of the support substrate, and
wherein the second direction is perpendicular to the first direction.

20. The flexible display device of claim 16, further comprising:
a space between each of the plurality of rigid portions, wherein the elastic portion fills the space between each of the plurality of rigid portions.
